(19) United States
(12) Patent Application Publication
(10) Pub. No.: US 2012/0241070 A1
(43) Pub. Date: Sep. 27, 2012

(54) METHOD OF MAKING A BIOCHEMICAL TEST STRIP

(76) Inventors: Jian-Hua CHEN, Hsinchu City (TW); Chi-Nan LEE, Hsinchu City (TW); Chien-Hsiang CHEN, Hsinchu City (TW)

(21) Appl. No.: 13/429,157

(22) Filed: Mar. 23, 2012

(30) Foreign Application Priority Data
Mar. 25, 2011 (TW) 100110410

(51) Int. Cl. H05K 3/10; H05K 3/12; C23C 28/02; H05K 13/04

(52) U.S. Cl. 156/60; 427/97.3; 205/184

(57) ABSTRACT

A method of making a biochemical test strip is disclosed which comprises the step of providing a substrate; the step of forming a metalizable primer on the area in which a circuit layout being to be formed; the step of forming a metal layer on the metalizable primer to form the circuit layout; using the substrate having the circuit layout to form the biochemical test strip.

### BACKGROUND OF THE INVENTION

(a) Field of the Invention

The invention relates to a method of making a biochemical test strip, particularly to a method of conveniently making a biochemical test strip having a metal electrode.

(b) Description of the Related Art

In the past, body check or examination can only be done in hospitals but nowadays accompanying with advance in medical technology and progress in concepts of health, there are many biochemical test devices, such as blood glucose monitoring system, for self-examination. Commercially available biochemical test devices have advantages of easy operation, small volume and quick examination.

FIG. 1 shows an exterior schematic diagram of a biochemical test strip according to the prior art. FIG. 2 shows a breakdown schematic diagram of the biochemical test strip of FIG. 1. As shown in FIGS. 1 and 2, biochemical test strip 100 is a blood glucose test strip, including electrode substrate 110, flow channel plate 120 and top plate 130. Electrode substrate 110 is formed by printing a plurality of electrodes and circuits on a substrate. Flow channel plate 120 defines notch 122 formed by penetrating the upper and lower surfaces of flow channel plate 120. In order to have blood flow smoothly, opening 135 is disposed at the position corresponding to notch 122 of flow channel plate 120.

When biochemical test strip 100 is fabricated, electrode substrate 110, flow channel plate 120 and top plate 130 should be laminated together to have flow channel plate 120 positioned between electrode substrate 110 and top plate 130 and then electrode substrate 110, flow channel plate 120 and top plate 130 define flow channel 150. The position of flow channel 150 corresponds to the position of notch 122 of flow channel plate 120 and flow channel 150 has inlet 125 and opening 135. During operation, a user drops a specimen on inlet 125 and blood flows from inlet 125 into flow channel 150. Blood flows in flow channel 150 due to capillary action and gas in flow channel 150 is expelled from opening 135.

Fluid type carbon ink or conductive ink can be used in printing electrodes but the carbon ink or conductive ink usually contains various chemical agents. After printing and baking to form electrodes, the residues of the chemical agents remain inside the electrodes and the reliability of the test result is affected.

Currently, there are a few methods for making a biochemical test strip. (1) A bulk metal material is used together with surface processing to make a biochemical test strip. (2) On a substrate, a metal film is formed and then patterned by a laser direct metal structuring technique to form an electrode pattern but more metal material is consumed and the laser processing time increases with the complexity of the pattern although it is a mature technique. (3) The technique of printed circuit board or semiconductor photolithography is used but a negative or photomask is required to define an electrode pattern and processes, such as coating photoresists, photolithographic processing, baking, etching, and lift-off processes, are required so that the production cost is relatively high, processes are complicated and more metal material is consumed.

Therefore, the method of making a biochemical test strip according to the prior art still needs further improvement.

### BRIEF SUMMARY OF THE INVENTION

One object of the invention is to provide a method for making a biochemical test strip. One object of the invention is to provide a method for conveniently making a biochemical test strip having a metal electrode. One object of the invention is to provide a method for making a biochemical test strip to reduce the usage of metal during the process of making the biochemical test strip.

One embodiment of the invention provides a method for making a biochemical test strip, comprising the following steps. A substrate is provided. A metalizable primer is formed on an area of the substrate which a circuit layout is to be formed on. On the metalizable primer, a metal layer is formed so as to form the circuit layout. The substrate having the circuit layout is used to form the biochemical test strip.

In one embodiment, the step of forming a metalizable primer on an area of the substrate which a circuit layout is to be formed on comprises: using a coating technique to form the metalizable primer on the area of the substrate which the circuit layout is to be formed on.

In one embodiment, the metalizable primer comprises one element selected from the group consisting of the following: Group VIII elements to Group XI elements in the Periodic table.

In one embodiment, the step of forming a metal layer on the metalizable primer comprises: placing the substrate formed with the metalizable primer in a chemical plating bath to form the metal layer by electroless metal deposition.

In one embodiment, the step of forming a metal layer on the metalizable primer further comprises: placing the substrate having the circuit layout at a preset temperature to carry out crosslinking.

In one embodiment, the step of using the substrate having the circuit layout to form the biochemical test strip comprises: laminating a flow channel plate and a top plate on the substrate having the circuit layout to have the substrate, the flow channel plate and the top plate define a flow channel.

According to one embodiment of the invention, a thicker biochemical test strip can be made more easily and have more scratch-resistance and better electrical conductivity. Between the substrate and the metal layer, the metalizable primer being a chemical substance is formed and can increase adhesiveness between the substrate and the metal layer. Besides, since a printing technique is used to define the pattern of the circuit layout, no etching is required and the production method is simpler. Metal material will not be wasted because there is no metal layer removal step.

Other objects and advantages of the invention can be better understood from the technical characteristics disclosed by the invention. In order to clarify the above mentioned and other objects and advantages of the invention, examples accompanying with figures are provided and described in details in the following.

### BRIEF DESCRIPTION OF THE DRAWINGS

FIG. 1 shows an exterior schematic diagram illustrating a biochemical test strip according to the prior art.

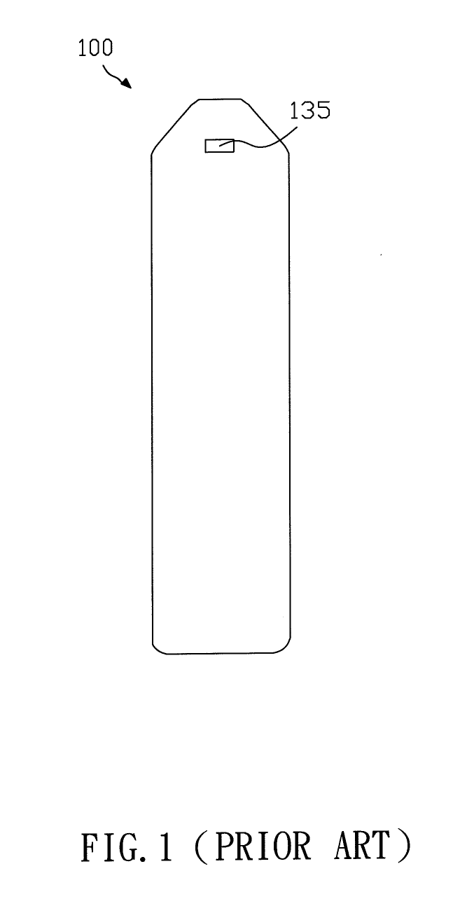

FIG. 2 shows a breakdown schematic diagram illustrating the biochemical test strip of FIG. 1.

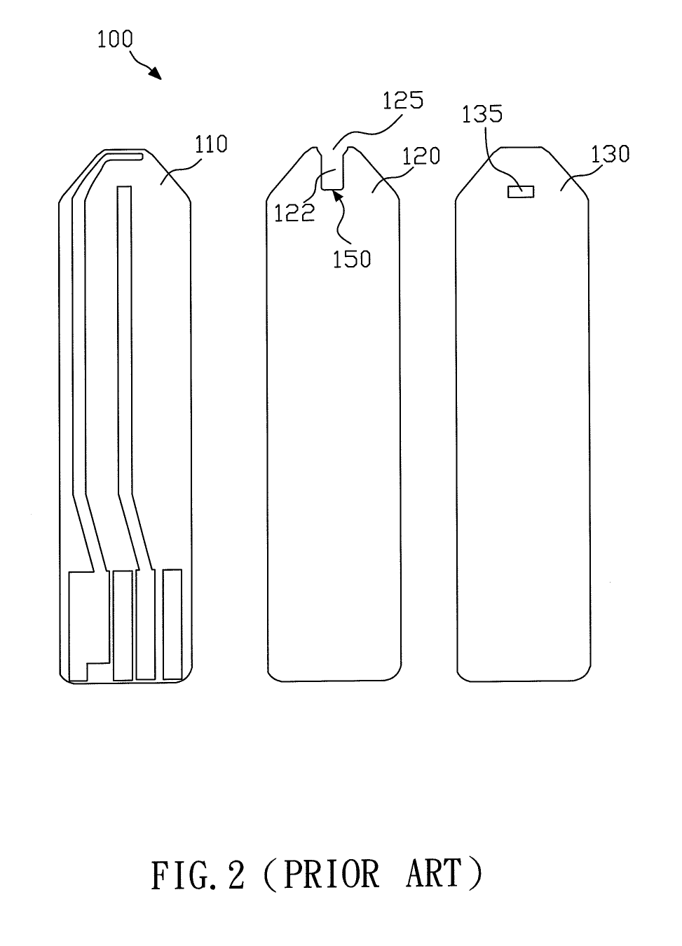

FIG. 3 shows a schematic diagram illustrating an electrode substrate of the biochemical test strip according to one embodiment of the invention.

FIG. 4 shows a flow chart of a method of making a biochemical test strip according to one embodiment of the invention.

FIG. 5 shows a cross-sectional schematic diagram illustrating each step of the method of making the electrode substrate of FIG. 3 along AA line.

### DETAILED DESCRIPTION OF THE INVENTION

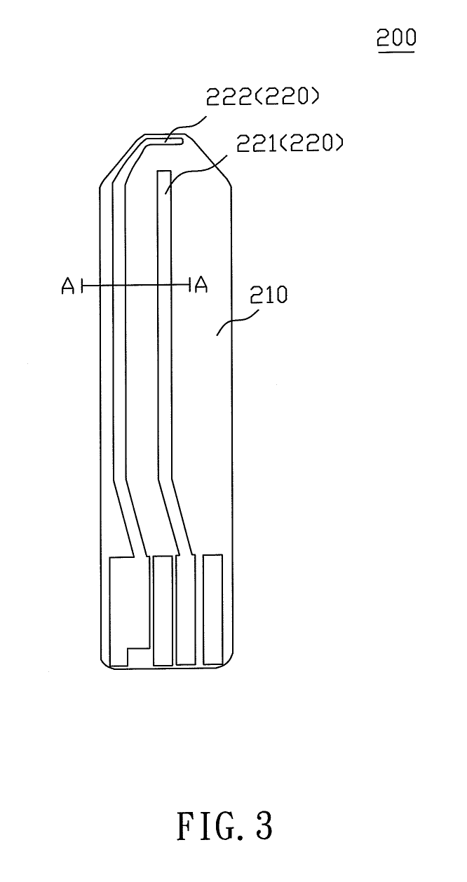

According to one embodiment of the invention, a biochemical test strip comprises an electrode plate, a flow channel plate and a top plate. FIG. 3 shows a schematic diagram illustrating an electrode plate of the biochemical test strip according to one embodiment of the invention. As shown in FIG. 3, electrode substrate 200 comprises substrate 210 and circuit layout 220 formed on substrate 210. Circuit layout 220 comprises first electrode 221 and second electrode 222.

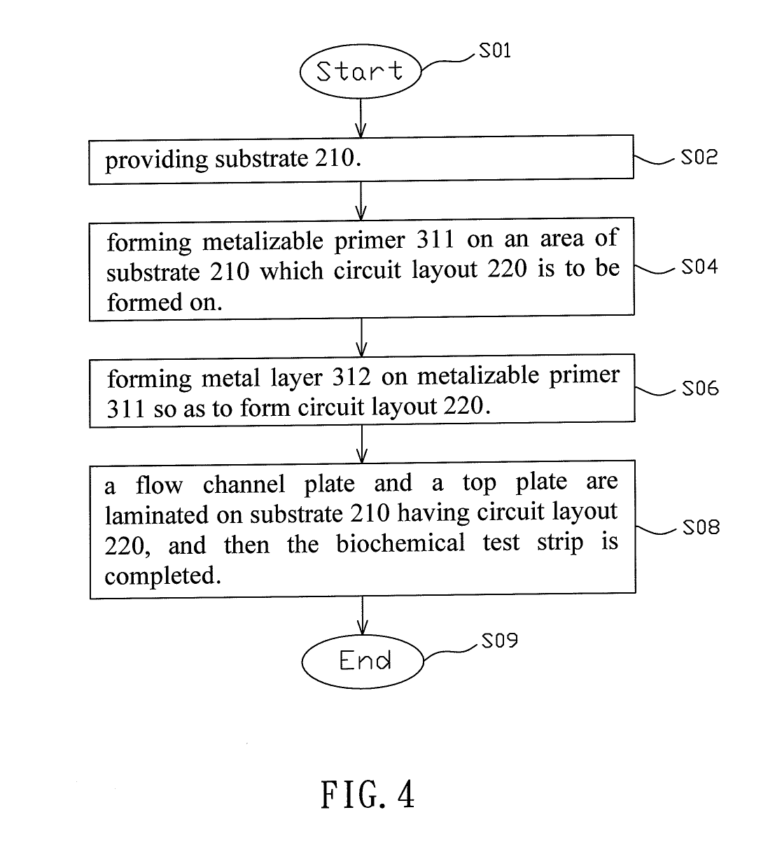

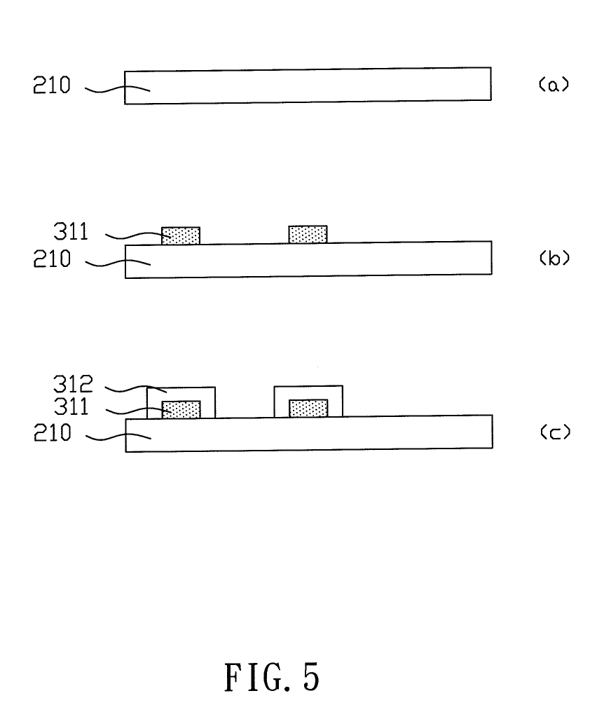

FIG. 4 shows a flow chart of a method of making a biochemical test strip according to one embodiment of the invention. FIG. 5 shows a cross-sectional schematic diagram illustrating each step of the method of making the electrode substrate of FIG. 3 along AA line. As shown in FIGS. 4 and 5, according to one embodiment of the invention, the method of making a biochemical test strip comprises the following steps.

As shown in FIG. 5(a), step S02: providing substrate 210. Substrate 210 is of insulation material and for example can be polyethylene terephthalate, polyethylene naphthalate, polypropylene, polycarbonate, ABS, polyetherimide, polysolfone, polyether sulfone, poyimide, poyamide imides, aromatic polyamide, etc.

As shown in FIG. 5(b), step S04: forming metalizable primer 311 on an area of substrate 210 which circuit layout 220 is to be formed on. In one embodiment, a printing technique is used to print metalizable primer 311 on the area of substrate 210 which circuit layout 220 is to be formed on so as to define the pattern of circuit layout 220. Besides, in one embodiment, a printing technique, inkjet printing technique, stamping technique, transfer printing technique or other coating technique is used to print metalizable primer 311 on the area of substrate 210 which circuit layout 220 is to be formed on.

Metalizable primer 311 comprises a metal compound as an activator suitable for electroless metal deposition but the material of the metalizable primer is not limited in the invention and can be any current or future to-be-developed material. In one embodiment, the metal of the metal compound can be one element selected from Group VIII elements to Group XI (Group VIII to Group IB) elements in the Periodic table.

Examples for the metal compound can be referred to EP34485, EP81438, and EP131195. In addition, metalizable primer 311 can further comprise an organic polymeric binder soluble in organic solvents or dispersed in water-containing formulations. Examples of the organic polymeric binder soluble can be referred to U.S. Pat. No. 4,549,006, U.S. Pat. No. 4,628,079 and U.S. Pat. No. 4,546,162. Metalizable primer 311 can further comprise fillers and additives, such as colorant, surfactant, leveling agents, deoxidizer, thickening agent, rheological additives, etc.

In one embodiment, metalizable primer 311 comprises 0.03 wt %-2.5 wt % (by weight) of element selected from Group VIII elements to Group XI elements as the activator; 3 wt %-20 wt % of organic polymeric binder; 1 wt %-20 wt % of filler; 57.5 wt %-95.97wt % of halogen-free solvent or solvent mixture having a flash point above 21° C. and a boiling point being at least 80° C. .

As shown in FIG. 5(c), step S06: forming metal layer 312 on metalizable primer 311 so as to form circuit layout 220 comprising first electrode 221 and second electrode 222. In one embodiment, substrate 210 formed with metalizable primer 311 is placed in a chemical plating bath to form metal layer 312 on metalizable primer 311 by electroless plating. Specifically, metalizable primer 311 can make metal ions in the chemical plating bath be reduced to metal on metalizable primer 311 and adsorbed on metalizable primer 311. Besides, in one embodiment, the chemical plating bath can comprise a copper metal compound such as copper sulfate, copper nitrate, copper carbonate, copper phosphate, copper chloride, copper cyanide, copper oxide and copper hydroxide as the oxidant to have reduced copper metal formed on metalizable primer 311. In one embodiment, the chemical plating bath can comprise a nickel metal compound such as nickel sulfate, nickel nitrate, nickel carbonate, nickel phosphate, nickel chloride, nickel cyanide, nickel oxide and nickel hydroxide as the oxidant to have reduced nickel metal formed on metalizable primer 311. In another embodiment, the chemical plating bath can comprise the other compound containing a to-be-plated metal which is to be formed into the metal layer and the to-be-plated metal is selected from the group consisting of the following: Al, Cu, Ti, Ni, Cr, W, Fe, Cd, Sn, Pb, Au, Pt, Ag, Ir, Os, Pd, Rh, and Ru. It should be understood that the to-be-plated metal is not limited to a specific type in the invention and metal layer 312 can be any current or future to-be developed conducting material.

Step S08: using the substrate having the circuit layout to form a biochemical test strip. In one embodiment, a flow channel plate and a top plate are laminated on substrate 210 having circuit layout 220, and then the biochemical test strip is completed. In this step, any current or future to-be developed technique can be used and is well-known to those who are skilled in the art. The details are thus not given hereinafter.

In one embodiment, the method of making a biochemical test strip further comprises step S20 (not shown): coating a chemical agent on a portion of circuit layout 220.

Besides, since electroless metal deposition for forming metal layer 312 has a slower speed, in a preset time, the thickness of metal layer 312 formed by electroless metal deposition is thinner than that of metal layer 312 formed by electroplating. In one embodiment, after metal layer 312 is formed, at least one electroplated metal layer is formed on metal layer 312. In one embodiment, at least one electroless-plated metal layer is chemically formed on metal layer 312. The material of the electroplated metal layer or electroless-plated metal layer can be the same as that of metal layer 312 or different from that of metal layer 312. The electroplated metal layer or electroless-plated metal layer increases the thickness of circuit layout 220 so as to increase conductivity. Besides, under some circumstances, surface treatment is performed on metal layer 312 to form the electroplated metal layer or electroless-plated metal layer and then a chemical agent is used, so that the signal of the biochemical test strip may be enhanced and more stable and have higher reliability.

In the prior art using metal to form a biochemical test strip, physical evaporation or sputtering is used to form a film having a thinner film thickness so that the subsequent process such as lift-off or etching process can be easily carried out. Compared to the prior art, the method of making a biochemical test strip according to one embodiment of the invention uses a wet process and can form a thicker film within a preset time and thus the production steps are simpler and faster to reduce production cost. Besides, in the prior art, it further requires the process such as etching, lithography, or laser direct structuring to pattern circuit layout 220 and has more complex processing. In addition, the removed portion of the metal layer is consumed additionally. In the embodiment of using noble metal as circuit layout 220, the production cost is further increased.

According one embodiment of the invention, a thicker biochemical test strip can be made more easily and have better scratch-resistance and electrical conductivity. Between substrate 210 and metal layer 312, metalizable primer 311 being a chemical substance is formed. Metalizable primer 311 can induce redox reaction of metal ions in the chemical plating bath and can increase adhesiveness between substrate 210 and metal layer 312. Besides, since a printing, inkjet printing, stamping or transfer printing technique is used to define the pattern of circuit layout 220, no etching, lithographic process or laser direct structuring is required and thus the production method is simpler. Metal material will not be wasted because there is no metal layer removal step.

In addition, since metalizable primer 311 has smaller particle size, after screen printing, the zigzag structure at the edges of the pattern of circuit layout 220 is also smaller than that according to the prior art using carbon ink or silver paste in screen printing. Compared to the test strip using a carbon electrode, the test result from the biochemical test strip having a metal electrode is more stable and has smaller variance. Therefore, the reliability of the biochemical test strip is higher.

Although the present invention has been fully described by the above embodiments, the embodiments should not constitute the limitation of the scope of the invention. Various modifications or changes can be made by those who are skilled in the art without deviating from the spirit of the invention. Any embodiment or claim of the present invention does not need to reach all the disclosed objects, advantages, and uniqueness of the invention. Besides, the abstract and the title are only used for assisting the search of the patent documentation and should not be construed as any limitation on the implementation range of the invention.

What is claimed is:

1. A method of making a biochemical test strip, the method comprising:
providing a substrate;
forming a metalizable primer on an area of the substrate which a circuit layout is to be formed on;
forming a metal layer on the metalizable primer so as to form the circuit layout; and
using the substrate having the circuit layout to form the biochemical test strip.

2. The method according to claim 1, wherein the step of forming a metalizable primer on an area of the substrate which a circuit layout is to be formed on comprises:
using a coating technique to form the metalizable primer on the area of the substrate which the circuit layout is to be formed on.

3. The method according to claim 2, wherein the coating technique is a printing technique, inkjet printing technique, stamping technique, or transfer printing technique.

4. The method according to claim 1, wherein the metalizable primer comprises one element selected from the group consisting of the following: Group VIII elements to Group XI elements in the Periodic table.

5. The method according to claim 1, wherein the step of forming a metal layer on the metalizable primer comprises:
placing the substrate formed with the metalizable primer in a chemical plating bath to chemically form the metal layer wherein the chemical plating bath comprises a compound containing a to-be-plated metal which is to be formed into the metal layer and the to-be-plated metal is selected from the group consisting of the following: Al, Cu, Ti, Ni, Cr, W, Fe, Cd, Sn, Pb, Au, Pt, Ag, Ir, Os, Pd, Rh, and Ru.

6. The method according to claim 5, wherein the chemical plating bath comprises a compound selected from the group consisting of the following:
copper sulfate, copper nitrate, copper carbonate, copper phosphate, copper chloride, copper cyanide, copper oxide and copper hydroxide; and the to-be-plated metal is copper.

7. The method according to claim 5, wherein the chemical plating bath comprises a compound selected from the group consisting of the following: nickel sulfate, nickel nitrate, nickel carbonate, nickel phosphate, nickel chloride, nickel cyanide, nickel oxide and nickel hydroxide; and the to-be-plated metal is nickel.

8. The method according to claim 5, further comprising:
forming at least one electroplated metal layer on the metal layer by electroplating.

9. The method according to claim 5, further comprising:
forming at least one electroless-plated metal layer on the metal layer by electroless metal deposition.

10. The method according to claim 1, wherein the step of using the substrate having the circuit layout to form the biochemical test strip comprises:
laminating a flow channel plate and a top plate on the substrate having the circuit layout to have the substrate, the flow channel plate and the top plate define a flow channel.

11. The method according to claim 1, wherein the step of using the substrate having the circuit layout to form the biochemical test strip comprises:
coating a chemical agent on a portion of the circuit layout.
